(19) United States
(12) Patent Application Publication
(10) Pub. No.: US 2015/0380411 A1
(43) Pub. Date: Dec. 31, 2015

(54) SEMICONDUCTOR STRUCTURE AND METHOD FOR MANUFACTURING THE SAME

(71) Applicants: Haizhou Yin, Poughkeepsie, NY (US); Yunfei Liu, Beijing (CN)

(72) Inventors: Haizhou Yin, Poughkeepsie, NY (US); Yunfei Liu, Beijing (CN)

(21) Appl. No.: 14/419,296

(22) PCT Filed: Aug. 17, 2012
(86) PCT No.: PCT/CN2012/080323

§ 371 Date: Sep. 1, 2015

(30) Foreign Application Priority Data
Aug. 3, 2012 (CN) 201210276441.5

(51) Int. Cl. H01L 27/092; H01L 21/8238; H01L 21/02; H01L 21/265; H01L 21/302; H01L 29/04; H01L 21/324

(52) U.S. Cl. CPC H01L 27/0924; H01L 29/045; H01L 21/823821; H01L 21/324; H01L 21/265; H01L 21/302; H01L 21/823828; H01L 21/02433

(57) ABSTRACT

The present invention provides a semiconductor structure, which comprises a semiconductor substrate and at least two semiconductor fins located on the semiconductor substrate, wherein: the at least two semiconductor fins are parallel to each other; and the parallel sidewall surfaces of the at least two semiconductor fins have different crystal planes. The present invention further provides a method for manufacturing aforesaid semiconductor structure. The technical solution provided in the present invention exhibits following advantages: it makes possible to form two parallel semiconductor fins with different sidewall crystal planes on the same substrate through changing crystal orientation of a part of the substrate; the two semiconductor fins individually have {100} sidewall crystal plane and {110} sidewall crystal plane, and are applied for forming NMOS and PMOS devices respectively; in this way, the overall performance of CMOS circuits is improved; besides, the two semiconductor fin structures are parallel to each other, such that it becomes less difficult to perform lithography and avoids wasting of wafer area.

The present application claims priority benefit of Chinese patent application No. 201210276441.5, filed on 3 Aug. 2012, entitled “SEMICONDUCTOR STRUCTURE AND METHOD FOR MANUFACTURING THE SAME”, which is herein incorporated by reference in its entirety.

### FIELD OF THE INVENTION

The present invention relates to a semiconductor structure with Fins and a method for manufacturing the same, and specifically, to a semiconductor fins applied in FinFETs and a method for manufacturing the same.

### BACKGROUND OF THE INVENTION

The traditional process for manufacturing bulk Si FinFETs (Fin Filed Effect Transistors) comprises forming an extended thin fin on a substrate, then forming a gate dielectric layer and a gate, and thereby forming a transistor. However, as revealed from researches, PMOS has highest hole mobility when transistor channels are directed along [110] crystal orientation of {110 } crystal plane, while NMOS has highest electron mobility when transistor channels are directed along [100] crystal orientation of {110} crystal plane (as shown in FIG. 1). As a result, in order to improve performance of CMOS circuits, a method in which finned semiconductor structures of PMOS and NMOS are formed on semiconductor fins with {110} and {100} side crystal planes, respectively, and the typical process comprises providing a substrate with {100} crystal plane and [110] crystal orientation. Specifically, the process further comprises etching the substrate to form first semiconductor fins along [110] crystal orientation of the substrate, etching the substrate to form second semiconductor fins along [100] crystal orientation of the substrate, and then forming PMOS and NMOS devices respectively based on the first semiconductor fins and the second semiconductor fins. FIG. 2a illustrates a structural diagram of a typical bulk Si FinFET, while FIG. 2b shows a structural view of crystal orientation of side surfaces of desired fins formed by FinFET processes of the prior art.

However, there may exist advantages. Because fin structures of PMOS and NMOS devices are not parallel, difficulty in lithography may increase, more wafer area than necessary may be wasted, which may lead to increased manufacturing cost.

Therefore, improvements for aforementioned processes are required.

### SUMMARY OF THE INVENTION

The present invention provides an improved semiconductor fin structure and a method for manufacturing the same, which has less difficulty in lithography and avoids wasting of wafer area.

In one aspect, the present invention provides a semiconductor structure comprising a semiconductor substrate and at least two semiconductor fins located on the semiconductor substrate.

The at least two semiconductor fins are parallel to each other.

The parallel side surfaces of the at least two semiconductor fins have different crystal planes.

The present invention further provides a method for manufacturing a semiconductor structure, which comprises following steps:

providing a first semiconductor substrate, which has a first crystal plane and a first crystal orientation predetermined on the first crystal plane ;

providing a second semiconductor substrate, which has a second crystal plane and a second crystal orientation predetermined on the second crystal plane;

turning the second semiconductor substrate with respect to the first semiconductor substrate, such that the first crystal orientation has a predetermined angle with respect to the second crystal orientation;

bonding the first semiconductor substrate and the second semiconductor substrate together;

selectively performing amorphization to a part of the first semiconductor substrate and a part of the second semiconductor substrate under the first semiconductor substrate;

performing selective solid phase epitaxy to the amorphous regions within the first semiconductor substrate and the second semiconductor substrate so as to form an epitaxial layer, which has the same crystal orientation as that of the second semiconductor substrate; and

forming at least two parallel semiconductor fins on the epitaxial layer and the first semiconductor substrate, respectively.

As compared to the prior art, the technical solution provided by the present invention has the following advantages.

It is possible to form two parallel semiconductor fins with different crystal planes on the same substrate by changing crystal orientation of a part of the substrate. The two semiconductor fins have {100} crystal plane and {110} crystal plane at sidesurfaces, and are applied to form NMOS and PMOS devices, respectively. In this way, the overall performance of CMOS circuits may be improved. Further, since the two semiconductor fin structures are parallel to each other, it becomes less difficult to perform lithography and avoids wasting of wafer area.

### BRIEF DESCRIPTION OF THE DRAWINGS

Other objectives, characteristics and advantages of the present invention are made more evident according to perusal of the following detailed description of exemplary embodiment(s) in conjunction with accompanying drawings, in which the same or similar reference signs in accompanying drawings denote the same or similar elements.

FIG. 1 illustrates diagrams of electron and hole mobility versus doping concentrations on a silicon substrate with different surface/channel direction.

FIG. 2a and FIG. 2b illustrates a structural diagram of a bulk Si FinFET and different channel direction orientations of FinFET on a wafer under manufacturing process of the prior art, respectively;

FIG. 3 illustrates a flowchart of a method for manufacturing a semiconductor structure according to the present invention; and

FIG. 4-FIG. 10 illustrate structural diagrams of a semiconductor structure manufactured at various stages according to the method of the present invention.

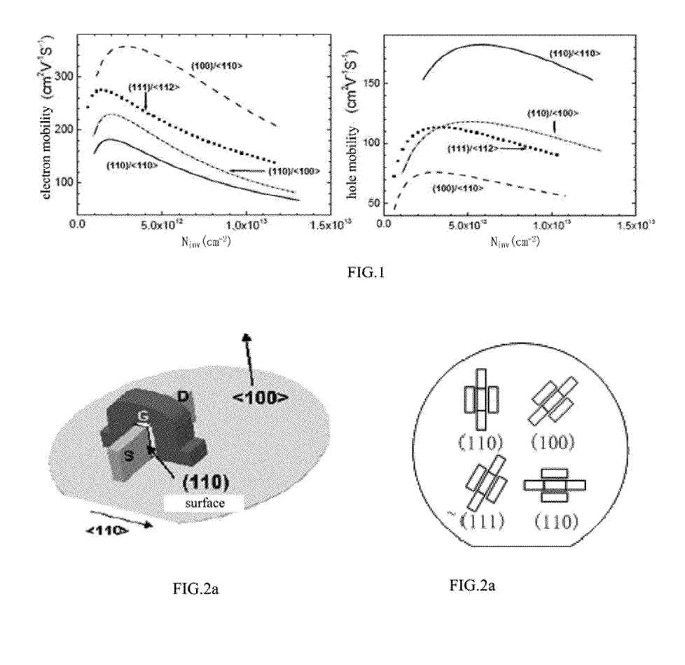

### DETAILED DESCRIPTION OF THE INVENTION

Here below, the present invention is described in detail in view of embodiments illustrated in the accompanying drawings. However, it should be understood that the description is exemplary, and are not intended to limit the scope of the present invention.

Various embodiments or examples are provided here below to implement different structures of the present invention. To simplify disclosure of the present invention, description of components and arrangements of specific examples is given below. Of course, they are illustrative only, and are not intended to limit the present invention. Moreover, in the present invention, reference numbers and/or letters may be repeated in different embodiments. Such repetition is for purposes of simplification and clarity, and does not denote any relationship between respective embodiments and/or arrangements under discussion. Furthermore, the present invention provides various examples for various processes and materials. However, it is obvious for a person of ordinary skill in the art that other processes and/or materials may be utilized alternatively. It is should be noted that the components shown in the drawings are not necessarily drawn to scale. Description of conventional components, processing technology and processes are omitted herein in order not to limit the present invention unnecessarily.

The semiconductor structure provided according to the present invention is suitable for circuits of CMOS devices. The manufacturing steps are set forth here below: firstly, bonding, in the same direction, semiconductor substrates with different crystal orientations, so as to form a combined semiconductor structure; next, implanting ions to amorphize a partial region of the structure, and forming a semiconductor structure with at least two crystal orientations by means of solid phase epitaxy; and then, forming parallel semiconductor fin structures on the semiconductor structure with different crystal orientations. Since the semiconductor fin structures have different crystal planes at side surfaces, it is possible to form devices of different types so as to improve performance of circuits.

The present invention has the following significant advantages.

A structure and a method for manufacturing the same are provided. Specifically, parallel semiconductor fin structures with different crystal planes at side surfaces are formed on the substrate, which makes it possible to improve performance of CMOS circuits. Parallel semiconductor fin structures may lead to less difficulty in performing lithography at subsequent steps, less complexity of dimensional structures and thereby improved utilization of wafer. Besides, in circuit designing, parallel fin structures may facilitate layout preparation and wiring, and may avoid fault.

The side surfaces of the parallel fin structures have different crystal planes, which thus are applicable for forming devices of different types. Side surfaces of the fin structures are parallel to the channel direction of devices; the fin structures whose side surfaces have {110} crystal plane are suitable for manufacturing PMOS devices, and the fin structures whose side surfaces have {100} crystal plane are suitable for manufacturing NMOS devices. Accordingly, devices of different types may be manufactured according to different crystal planes of semiconductor fin structures, thereby enhancing overall performance of the devices.

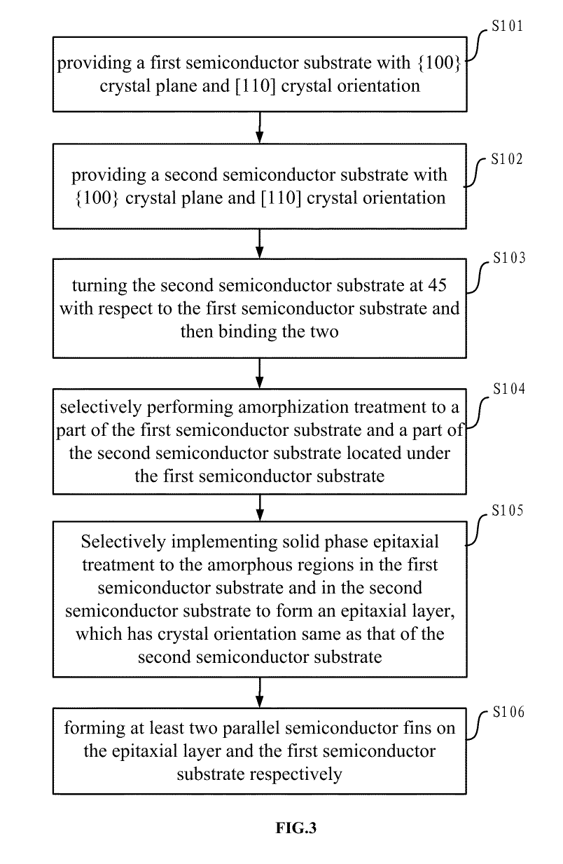

FIG. 3 illustrates a flowchart of an embodiment of the present invention.

First, at steps S101 and S102, a first semiconductor substrate and a second semiconductor substrate having {100} crystal plane are provided. [110] crystal orientation are determined on the first semiconductor substrate and the second semiconductor substrate, respectively, wherein [110] crystal orientation is parallel to surfaces of the first and second semiconductor substrates. Then, at step S103, the second semiconductor substrate is turned at 45° with respect to the first semiconductor substrate such that their respective [110] crystal orientations have an acute angle of 45° with respect to each other. Next, the first semiconductor substrate and the second semiconductor substrate are bonded together. At step S104, amorphization is selectively performed to a part of the first semiconductor substrate and a part of the second semiconductor substrate located under the first semiconductor substrate. At step S105, selective solid phase epitaxy is performed to the amorphous regions within the first semiconductor substrate and the second semiconductor substrate, such that an epitaxial layer has the same crystal orientation as that of the second semiconductor substrate. Finally, at step S106, at least two parallel semiconductor fins are formed on the epitaxial layer and the first semiconductor substrate, respectively, wherein the crystal plane at side surfaces of the first semiconductor fin formed on the epitaxial layer may be {110} or {100}. Since respective crystal orientations on the epitaxial layer have an angle of 45° with respect to corresponding crystal orientations on the first semiconductor substrate, when the second semiconductor fin, which is parallel to the first semiconductor fin, is formed on the first semiconductor substrate, the crystal plane at side surfaces of the second semiconductor fin is {100} or {110}. In a case in which the crystal plane at side surfaces of a semiconductor fin is {100}, the semiconductor fin may be used to manufacture NMOS devices. While in a case in which the crystal plane at side surfaces of a semiconductor fin is {110}, the semiconductor fin may be used to manufacture PMOS devices. Therefore, mobility of carriers may be improved and performance of the devices may be enhanced. By forming parallel semiconductor fins with different crystal planes at side surfaces on the same substrate, difficulty in manufacturing process may be alleviated and utilization of the substrate may be improved.

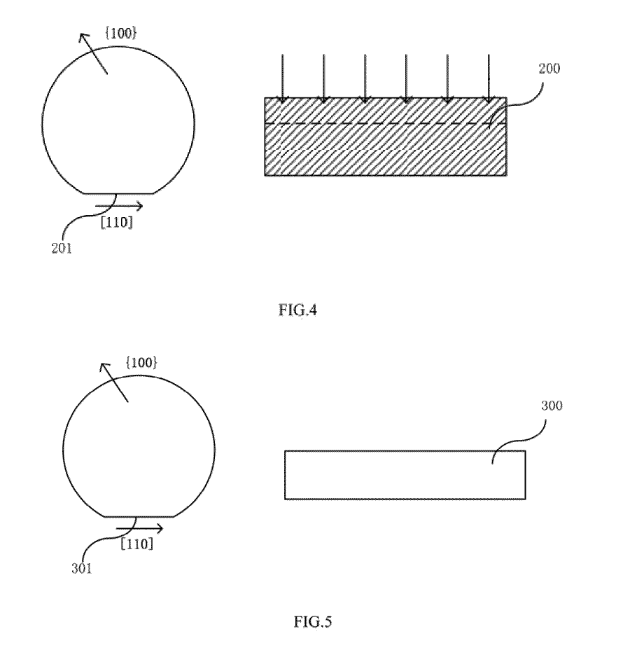

Here below, the manufacturing process according to an embodiment of the present invention is described with reference to FIG. 4 to FIG. 10.

First, as shown in FIG. 4, a first semiconductor substrate 200 is provided. The material thereof may be an elementary semiconductor like Ge, and is preferably Si. The first semiconductor substrate usually has a round shape with a conventional diameter of, for example, about 50 mm, 100 mm, 200 mm, 300 mm and 450 mm, with a notch or an alignment edge 201 for distinguishing or aligning crystal orientations. The first semiconductor substrate may have standard thickness, which may vary from 400 mm to 1000 mm. The first semiconductor substrate preferably has {100} crystal plane, and the alignment edge 201 preferably has [110] crystal orientation.

Next, in order to make a thin first semiconductor substrate, SMARTCUT process may be performed to implant H ions into the first semiconductor substrate 300 from one of the surfaces, wherein the implanting dose may be in the range of 10¹⁶˜2×10⁷ and the implanting depth may be However, it should be noted that the implanting depth is preferably greater than the height of the semiconductor fin structure to be formed finally. Then, in the subsequent process, the first semiconductor substrate with a thickness of 1˜2 μm is obtained by a peeling process.

Next, as shown in FIG. 5, a second semiconductor substrate 300 is provided. The material thereof is preferably the same as that of the first semiconductor substrate, and the doping configurations thereof are not limited. The second semiconductor substrate usually has a round shape with a diameter of, for example, 50 mm, 100 mm, 200 mm, 300 mm and 450 mm, and may have a notch or an alignment edge 301 for distinguishing or aligning crystal orientation. The second semiconductor substrate may have a standard thickness, which may vary from 400 mm to 1000 mm The second semiconductor substrate preferably has {100} crystal plane and, the alignment edge 301 preferably has [110] crystal orientation. The size and crystal plane of the first semiconductor substrate are the same as those of the second semiconductor substrate.

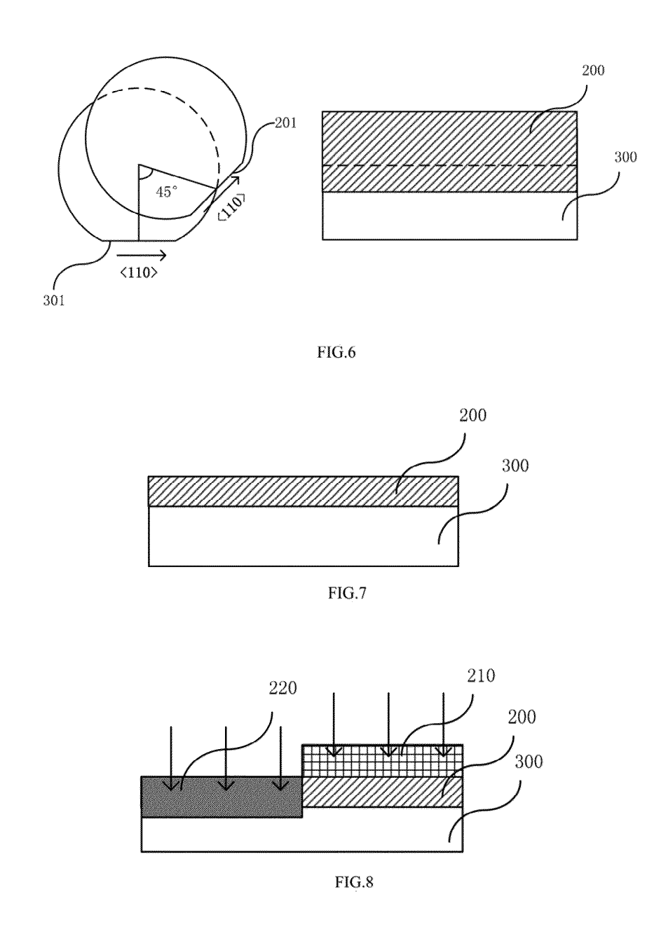

Then, as shown in FIG. 6, the alignment edge 301 of the second semiconductor substrate is turned at 45° with respect to the alignment edge 201 of the first semiconductor substrate. The H-implanted surface of the first semiconductor substrate is directly bonded to a surface of the second semiconductor substrate. The bonding process is carried out as follows: polishing, washing and activating (OFF solution or plasma) the surface of the semiconductor substrate; and bonding surfaces of the semiconductor substrates together at room temperature.

Then, as shown in FIG. 7, the bonded structure is annealed at a temperature of 400° C.˜600° C., preferably 500° C., for a period of 30 min˜120 min. The annealing is intended to peel off the H layer, which has been implanted into the substrate, from the substrate structure.

Then, the bonded structure is processed by annealing, surface polishing and thinning again. The annealing may be performed at a temperature of 1000° C. for a period of about 30 min˜8 hrs. The annealing is intended to enhance the bonding between the first semiconductor substrate and the second semiconductor substrate. After the surface polishing and thinning, the peeled portion of the first semiconductor substrate, which has been bonded to the second semiconductor substrate, preferably has a thickness slightly greater than the height of the semiconductor fin. Finally, a combined structure of the first semiconductor substrate and the second semiconductor substrate with a predetermined depth is fabricated.

Then, as shown in FIG. 8, a patterned mask layer 210 is formed on the first semiconductor substrate, and ions are implanted to form an amorphous region 220 within the first semiconductor substrate and the second semiconductor substrate. The mask layer is preferably made from a photoresist layer, which specifically may be a photoresist mask formed by a lithography process including exposing and developing, e-beam lithography or other process as appropriate. The ion implantation is intended to amorphize the implanted semiconductor region. Specifically, the ions for implantation are preferably Ge, the implanting dose may be in the range of about 1×10¹³/cm²˜1×10¹⁵/cm², and the implanting energy may be 400 keV. The depth of ion implantation is greater than the thickness of the first semiconductor substrate so as to amorphize a part of the second semiconductor substrate.

Then, as shown in FIG. 9, the mask layer is removed and selective solid phase epitaxy is performed to the amorphous region. The solid phase epitaxy enables ordering and re-crystallizing of the amorphous region, thereby forming an epitaxial layer 200 with the same crystal plane and crystal orientation ({100} crystal plane, [110] crystal orientation) as those of the second semiconductor substrate.

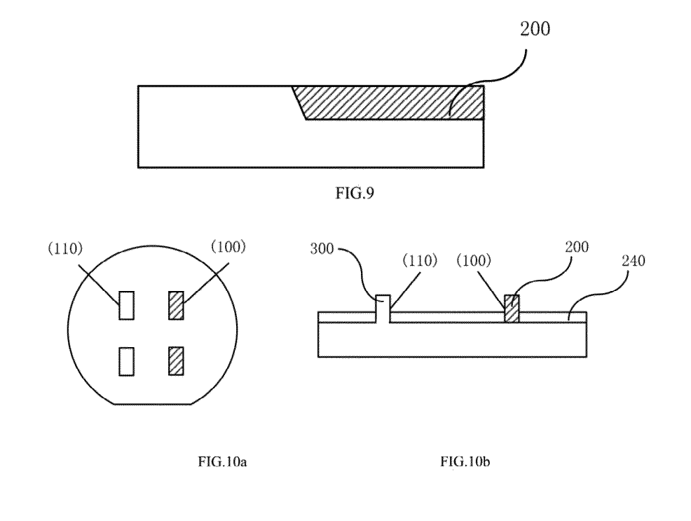

Then, as shown in FIG. 10a and FIG. 10b, a first semiconductor fin 200 and a second semiconductor fin 300 are formed. First, an etching mask layer is formed on the surface of the structure. Then, the first semiconductor fin and the second semiconductor fin, which are parallel to each other, are formed at an angle of 0° or 90° with respect to the alignment edge of the structure by wet etching or dry etching. The crystal plane at side surfaces of the first semiconductor fin structure is determined by crystal orientation of the alignment edge of the first semiconductor substrate, i.e. {110}. The crystal plane at side surfaces of the second semiconductor fin is determined by crystal orientation resulted from turning the alignment edge of the second semiconductor substrate at 45°, i.e. {100}. Finally, the semiconductor structure is formed.

Then, gate dielectric layers are formed on surfaces of the first semiconductor fin and the second semiconductor fin, and then gates are formed on the gate dielectric layers. Finally, PMOS and NMOS devices are formed on the basis of the first semiconductor fin and the second semiconductor fin, respectively. The thickness of the gate dielectric layers may be about 1 nm-15 nm, and may be formed of a high-K or low-K material. The thickness of the gates may be about 20-90 nm, and may be formed of a material selected from a group consisting of Poly-Si, Ti, Co, Ni, Al, W, alloy and metallic silicides.

Here below, the semiconductor structure manufactured according to the present invention is described.

The present invention provides a semiconductor structure, which comprises a semiconductor substrate, at least two semiconductor fins located on the semiconductor substrate, wherein the at least two semiconductor fins are parallel to each other; and the parallel crystal planes at side surfaces of the at least two semiconductor fins are different from each other.

The material for the semiconductor substrate is preferably Si or Ge, and the doping type and concentration thereof have been predetermined. The crystal plane of the semiconductor substrate is preferably {100} crystal plane, and the parallel crystal planes at side surfaces of the two semiconductor fins are {100} and {110} crystal planes, respectively.

The semiconductor substrate comprises a first semiconductor substrate, a second semiconductor substrate located under the first semiconductor substrate, and an epitaxial layer of the second semiconductor substrate. The at least two semiconductor fins are formed respectively on the first semiconductor substrate and the epitaxial layer of the second semiconductor substrate. The first and the second semiconductor substrates are bonded together, and [110] crystal orientations thereof have an angle of 45° with respect to each other. The semiconductor fins having crystal plane of {100} and {110} at side surfaces are applicable for manufacturing NMOS and PMOS devices, respectively.

According to another aspect of the present invention, an embodiment in which a semiconductor structure having three different crystal planes at surfaces is provided.

First, a first, second and third semiconductor substrates are provided. The materials may be preferably Si, and may be an element semiconductor such as Ge. The first, second and third semiconductor substrates usually have a round shape with a diameter of, for example 50 mm, 100 mm, 200 mm, 300 mm and 450 mm, and may have a notch or an alignment edge for distinguishing or aligning crystal orientation. The first, second and third semiconductor substrates may have standard thickness from 400 mm to 1000 mm The first, second and third semiconductor substrates preferably have {100} crystal plane, and the alignment edges thereof preferably have [110] crystal orientation.

Then, according to guidelines of the SMARTCUT process, H ions are implanted into one side surface of the first semiconductor substrate. The implanting dose may be in the range of 10¹⁶˜2×10⁷ and the implanting depth may be 1˜2 μm. It should be noted that the implanting depth is preferably greater than the height of the semiconductor fin structure to be formed.

Then, the alignment edge of the second semiconductor substrate is turned at 45° with respect to the alignment edge of the first semiconductor substrate. The H-ions implanted surface of the first semiconductor is bonded directly to one surface of the second semiconductor substrate. The bonding process may be carried out by polishing, washing and activating (OH⁻ solution or plasma) surfaces of the semiconductor substrates; and bonding surfaces of the semiconductor substrates together at room temperature.

Then, the bonded structure is annealed at a temperature of 400° C.˜600° C., preferably 500° C., for a period of about 30 min˜120 min. The annealing is intended to peel off the H-ion implanted layer in the substrate from the substrate structure.

Then, the bonded structure is processed by annealing, surface polishing and thinning again. The annealing may be performed at a temperature of 1000° C. for a period of about 30 min˜8 hrs. The annealing this time is intended to enhance bonding intensity between the first semiconductor substrate and the second semiconductor substrate. After surface polishing, a combined structure of the first semiconductor substrate and the second semiconductor substrate as desired is fabricated.

Then, the third semiconductor substrate is processed by aforementioned processes, namely, implanting, bonding, annealing and peeling, such that a third semiconductor substrate structure is additionally formed based on the combined structure of the first semiconductor substrate and the second semiconductor substrate. However, it should be noted that, prior to implementation of the bonding process, the third semiconductor is turned at 30° with respect to the first semiconductor substrate. And the thickness of the third semiconductor substrate located on aforementioned structure is slightly greater than the height of the semiconductor fins.

Then, a patterned mask layer is formed on the third semiconductor substrate. Ions are implanted such that amorphous regions are formed in a part of the third semiconductor substrate and a part of the first semiconductor substrate, and amorphous regions are formed in a part of the third semiconductor substrate, in the first semiconductor substrate and in a part of the second semiconductor substrate. The mask layer is preferably a photoresist mask, which is specifically a photoresist mask formed by lithography including exposing and developing process, e-beam lithography or other process as appropriate. The ion implantation is intended to amorphize the implanted semiconductor regions; specifically, the particles for implantation are preferably Ge, implanting volume is in the range of 1×10¹³/cm²˜1×10¹⁵/cm², and implanting energy is 400 keV; the depth of ion implantation is slightly greater than the thickness of the first semiconductor substrate so as to amorphize a part of the second semiconductor substrate.

Then, the mask layer is removed and selective solid phase epitaxy is performed to the amorphous regions. Said solid phase epitaxy enables the amorphous regions to be in and re-crystallize, thereby forming an epitaxial layer structure. A portion of the epitaxial layer structure has the same crystal plane and crystal orientation ({100} crystal plane, [110] crystal orientation) as those of the first semiconductor substrate, while a portion of the epitaxial layer structure has the same crystal plane and crystal orientation ({100} crystal plane, [100] crystal orientation) as those of the second semiconductor substrate.

Then, first, second and third semiconductor fin structures are formed. First, an etching mask layer is formed on the surface of the structure; then, the first, second and third semiconductor fins, which are parallel to each other, are formed along 0° or 90° direction of the alignment edge of the structure by means of wet etching or dry etching. The sidewall crystal plane of the first semiconductor fin structure is determined by crystal orientation of the alignment edge of the first semiconductor substrate, i.e. {110}; the sidewall crystal plane of the second semiconductor fin is determined by crystal orientation resulted from turning the alignment edge of the second semiconductor substrate at 45°, i.e. {100}; and the sidewall crystal plane of the third semiconductor fin is determined by crystal orientation resulted from turning the alignment edge of the third semiconductor substrate at 30°, i.e. {210}. So far, the semiconductor structure is formed.

According to the semiconductor structure and the manufacturing method provided by the present invention, two types of parallel semiconductor fins with different sidewall crystal planes may be formed on the same substrate through changing crystal orientation of a part of the substrate in the same direction; the sidewall crystal planes of the two semiconductor fins are {100} and {110} respectively, and may be applied to manufacture NMOS and PMOS devices, which shows improved overall performance in CMOS circuits; since the two types of semiconductor fin structures are parallel, it becomes less difficult to perform lithography, and avoids wasting of wafer area and lessens complexity of the dimensional structure, thereby boosting utility of the wafer area. Meanwhile, at the designing stage, parallel fin structures make it easier for outlining, wiring so as to restrain occurrence of other fault mechanisms.

Although the exemplary embodiments and their advantages have been described at length herein, it should be understood that various alternations, substitutions and modifications may be made to the embodiments without departing from the spirit of the present invention and the scope as defined by the appended claims. As for other examples, it may be easily appreciated by a person of ordinary skill in the art that the order of the process steps may be changed without departing from the scope of the present invention.

In addition, the scope, to which the present invention is applied, is not limited to the process, mechanism, manufacture, material composition, means, methods and steps described in the specific embodiments in the specification. According to the disclosure of the present invention, a person of ordinary skill in the art should readily appreciate from the disclosure of the present invention that the process, mechanism, manufacture, material composition, means, methods and steps currently existing or to be developed in future, which perform substantially the same functions or achieve substantially the same as that in the corresponding embodiments described in the present invention, may be applied according to the present invention. Therefore, it is intended that the scope of the appended claims of the present invention includes these process, mechanism, manufacture, material composition, means, methods or steps.

1. A semiconductor structure, comprising: a semiconductor substrate and at least two semiconductor fins located on the semiconductor substrate, wherein:
the at least two semiconductor fins are parallel to each other; and
the parallel side surfaces of the at least two semiconductor fins have different crystal planes.

2. The semiconductor structure of claim 1, wherein the parallel side surfaces of the two semiconductor fins have {100} and {110} crystal planes, respectively.

3. The semiconductor structure of claim 1, wherein the semiconductor substrate comprises a first semiconductor substrate, a second semiconductor substrate located under the first semiconductor substrate and an epitaxial layer of the second semiconductor substrate.

4. The semiconductor structure of claim 1, wherein the at least two semiconductor fins are formed on the first semiconductor substrate and the epitaxial layer of the second semiconductor substrate.

5. The semiconductor substrate of claim 3, wherein the first and the second semiconductor substrates are bonded together, and their [110] crystal orientations have an angle of 45° with respect to each other.

6. The semiconductor structure of claim 2, wherein the semiconductor fins with side surfaces of crystal planes {100} and {110} respectively are used to manufacture NMOS and PMOS devices.

7. The semiconductor structure of claim 1, further comprising a third semiconductor fin; the third semiconductor fin is parallel to the at least two semiconductor fins, and the third semiconductor fin and the at least two semiconductor fins have different crystal planes of the parallel side surfaces thereof.

8. The semiconductor structure of claim 7, wherein the semiconductor substrate is formed from the first semiconductor substrate, the second semiconductor substrate located under the first semiconductor substrate, the third semiconductor substrate and epitaxial layers of the second and third semiconductor substrates.

9. The semiconductor structure of claim 7, wherein at least two semiconductor fins are formed respectively on the first semiconductor substrate and the epitaxial layer of the second semiconductor substrate, and the third semiconductor fin is formed on the epitaxial layer of the third semiconductor substrate.

10. A method for manufacturing a semiconductor structure, comprising:
providing a first semiconductor substrate having a first crystal plane, wherein the first crystal plane has a predetermined first crystal orientation thereon;
providing a second semiconductor substrate having a second crystal plane, wherein the second crystal plane has a predetermined second crystal orientation thereon;
turning the second semiconductor substrate with respect to the first semiconductor substrate, such that the first crystal orientation has a predetermined angle with respect to the second crystal orientation;
bonding the first semiconductor substrate and the second semiconductor substrate together;
selectively performing amorphization to a part of the first semiconductor substrate and a part of the second semiconductor substrate located under the first semiconductor substrate;
selectively performing solid phase epitaxy to the amorphous regions in the first semiconductor substrate and in the second semiconductor substrate to form an epitaxial layer, wherein the epitaxial layer has the same crystal orientation as that of the second semiconductor substrate; and
forming at least two parallel semiconductor fins on the epitaxial layer and the first semiconductor substrate, respectively.

11. The method for manufacturing a semiconductor structure of claim 10, wherein both the first and the second crystal planes are {100} crystal planes, and both the first and the second crystal orientations are {110} crystal orientations.

12. The method for manufacturing a semiconductor structure of claim 10, wherein the predetermined angle is 45°.

13. The method for manufacturing a semiconductor structure of claim 10, further comprising:
implanting H ions into the first semiconductor substrate from one side surface;
bonding the H-implanted surface of the first semiconductor substrate to the second semiconductor substrate;
annealing the first and the second semiconductor substrate, and removing the first semiconductor substrate except the H-implanted part; and
thinning and polishing the remaining bonded structure after the removing process.

14. The method for manufacturing a semiconductor structure of claim 10, wherein the amorphization comprises:
forming a patterned mask layer on the first semiconductor substrate;
implanting ions to form amorphous regions with predetermined depth on the first semiconductor substrate and a part of the second semiconductor substrate under the first semiconductor substrate.

15. The method for manufacturing a semiconductor structure of claim 14, wherein Ge is used for ion implantation, the implanting dose is in the range of 1×10¹³/cm²˜1×10¹⁵/cm², and the implanting energy is 400 keV, and wherein the depth of ion implantation is greater than the thickness of the first semiconductor substrate so as to amorphize a part of the second semiconductor substrate.

16. The method for manufacturing a semiconductor structure of claim 14, wherein the predetermined depth is greater than the thickness of the first semiconductor substrate.

17. The method for manufacturing a semiconductor structure of claim 10, wherein the bonding process comprises following steps:
processing surfaces of the first and the second semiconductor substrates;
bonding the H-ion implanted surface of the first semiconductor substrate to the surface of the second semiconductor substrate; and
annealing to form bonding therebetween.

18. The method for manufacturing a semiconductor structure of claim 10, wherein formation of the at least two semiconductor fins comprises:
forming patterned mask layers on the first semiconductor substrate and the epitaxial layer; and
etching to forming the at least two semiconductor fins on the substrate.

19. The method for manufacturing a semiconductor structure of claim 10, further comprising:
forming gate dielectric layers on the at least two semiconductor fins; and
forming gates on the gate dielectric layers.

20. The method for manufacturing a semiconductor structure of claim 10, wherein the crystal plane of the side surface on the fin within the region of the first semiconductor substrate is {110} crystal plane, the crystal plane of the side surface on the fin within the region of the epitaxial layer is {100} crystal plane; and
forming a PMOS device with the fin located within the region of the first semiconductor substrate, and forming an NMOS device with the fin located within the region of the epitaxial layer.

21. (canceled)
